(19) United States
(12) Patent Application Publication
(10) Pub. No.: US 2026/0187320 A1
(43) Pub. Date: Jul. 2, 2026

(54) Automatic Sensor fusion in a digital twin

(71) Applicant: PassiveLogic, Inc., Holladay, UT (US)

(72) Inventor: Troy Aaron Harvey, Holladay, UT (US)

(21) Appl. No.: 19/437,714

(22) Filed: Dec. 31, 2025

Related U.S. Application Data
(60) Provisional application No. 63/741,232, filed on Jan. 2, 2025.

(51) Int. Cl. G06F 30/27; G06N 3/048; G06N 3/063

(52) U.S. Cl. CPC G06F 30/27; G06N 3/048; G06N 3/063

(57) ABSTRACT

Various embodiments relate to a method, apparatus, and machine-readable storage medium for simulating a sensor value including one or more of the following: receiving a real sensor value from a sensor device at a first location within a system; propagating the real sensor value through a digital twin simulation of the system from a first simulated location associated with the first location to a second simulated location associated with a second location within the system, wherein propagating comprises applying at least one physics-based transfer function to the real sensor value; determining that a virtual sensor value should be generated for the second location within the system; and extracting the virtual sensor value from the second simulated location of the digital twin simulation.

### RELATED APPLICATIONS

The present application claims priority to U.S. provisional patent application Ser. No. 63/741,232, filed Jan. 2, 2024, the entire disclosure of which is incorporated herein by reference. The present application is a continuation-in-part of U.S. patent application Ser. No. 17/208,036, filed Mar. 22, 2021, which claims priority to provisional patent application 62/704,976, filed Jun. 5, 2020, the entire disclosures of which are hereby incorporated by reference. The present application is a continuation-in-part of U.S. patent application Ser. No. 17/336,640, filed Jun. 2, 2021, which claims priority to provisional patent application 62/704,976, filed Jun. 5, 2020, the entire disclosures of which are hereby incorporated by reference. The present application is a continuation-in-part of U.S. patent application Ser. No. 18/403,542, filed Jan. 3, 2024, which is a continuation of patent application Ser. No. 17/228,119, filed Apr. 12, 2021, and which claims priority to provisional patent application 62/704,976, filed Jun. 5, 2020, the entire disclosures of which are hereby incorporated by reference. The present application is a continuation-in-part of U.S. patent application Ser. No. 17/143,796, filed Jan. 7, 2021, the entire disclosure of which is hereby incorporated by reference.

### TECHNICAL FIELD

Various embodiments described herein relate to sensors and, more specifically but not exclusively, to simulation of sensor values.

### BACKGROUND

In the field of systems control, sensors are important components to give a controller a view to the current state of a system so that decisions can be made regarding how to achieve a desired future state. For example, in a simple system, a controller may wish to control the temperature of a room. Without a means to sense the temperature in that room, the controller would typically have no idea whether the room should be heated or cooled to bring the room to the desired temperature.

As the system under control becomes more complex, the number of sensors that might be utilized expands quickly. More sensors of the same type may be disposed throughout the system at different points (e.g., many temperature sensors disposed throughout a building) or sensors of multiple different types may be deployed to measure different parameters (e.g. temperature, humidity, pressure, sound, light, etc. sensors). While more information is generally better, each additional sensor comes with cost: the monetary cost of the sensor hardware and the power to operate it, the physical space cost to place the sensor in a location where it will not interfere with other processes, the computing resources cost on the network bandwidth and controller processing cycles, and so forth. In many systems deployments, decisions must be made that analyze this trade-off between the comprehensiveness of the view of the system and the costs associated with that view.

### SUMMARY

According to various embodiments described herein, methods and systems are described that enable the creation of virtual sensors in the absences of real world physical sensors. The virtual sensors may provide data for use by a controller or other non-control applications. These virtual sensor readings may be generating by making inferences based on other information that is known about the system. For example, if the outside temperature is known to be 50 degrees and a heater device is known to have been set to a temperature of 70 degrees, it might be inferred that the temperature near the heater device is also close to 70 degrees.

Various embodiments utilize a digital twin of the system to model at least some of the known information about a system and support inferences about virtual sensors. For example, knowing the arrangement and physical properties of a building to be heated, known temperature values (e.g., from outside) can be propagated through the building in a simulation to infer what the temperature of different rooms are likely to be.

While various embodiments are described herein in connection with heating, ventilation, and cooling (HVAC) applications and in connection with temperature sensors, it will be apparent to those of skill in the art that the techniques described herein for inferring virtual sensor values may be adapted and applied to virtually any systems, sensor types, and applications. Modifications for implementing such alternative embodiments will be apparent to those of skill in the art.

Various embodiments described herein relate to a method for simulating a sensor value including one or more of the following: receiving a real sensor value from a sensor device at a first location within a system; propagating the real sensor value through a digital twin simulation of the system from a first simulated location associated with the first location to a second simulated location associated with a second location within the system, wherein propagating comprises applying at least one physics-based transfer function to the real sensor value; determining that a virtual sensor value should be generated for the second location within the system; and extracting the virtual sensor value from the second simulated location of the digital twin simulation.

Various embodiments described herein relate to an apparatus for simulating a sensor value including one or more of the following: a memory storing a digital twin simulation of a system; and a processor configured to: receive a real sensor value from a sensor device at a first location within the system, propagate the real sensor value through the digital twin simulation from a first simulated location associated with the first location to a second simulated location associated with a second location within the system, wherein propagating comprises applying at least one physics-based transfer function to the real sensor value, determine that a virtual sensor value should be generated for the second location within the system, and extract the virtual sensor value from the second simulated location of the digital twin simulation.

Various embodiments described herein relate to a non-transitory machine-readable storage medium encoded with instructions for execution by a processor for simulating a sensor value including one or more of the following: instructions for receiving a real sensor value from a sensor device at a first location within a system; instructions for propagating the real sensor value through a digital twin simulation of the system from a first simulated location associated with the first location to a second simulated location associated with a second location within the system, wherein propagating comprises applying at least one physics-based transfer function to the real sensor value; instructions for determining that a virtual sensor value should be generated for the second location within the system; and instructions for extracting the virtual sensor value from the second simulated location of the digital twin simulation.

Various embodiments are described wherein the real sensor value has a first value type; the virtual sensor value has a second value type different from the first value type; and the at least one physics-based transfer function comprises a function that translates from the first value type to the second value type.

Various embodiments are described wherein the digital twin simulation comprises a neural network, the first simulated location comprises a first neuron of the neural network, the second simulated location comprises a second neuron of the neural network, and the at least one physics-based transfer function is used as at least part of an activation function within the neural network.

Various embodiments are described wherein determining that the virtual sensor value should be generated comprises receiving a request from an application for the virtual sensor value via an application programmer interface.

Various embodiments are described wherein the system comprises at least one of a building and a system of HVAC equipment.

Various embodiments are described wherein extracting the virtual sensor value comprises applying a conversion function to at least one value associated in the digital twin simulation with the second simulated location to produce the virtual sensor value.

Various embodiments are described wherein propagating the real sensor value through the digital twin simulation additionally comprises propagating an additional real sensor value received from an additional sensor device from a third simulated location to the second simulated location, whereby the virtual sensor value is based on both the real sensor value and the additional real sensor value.

### BRIEF DESCRIPTION OF THE DRAWINGS

In order to better understand various example embodiments, reference is made to the accompanying drawings, wherein:

FIG. 1 illustrates an example of an environment for operation of various embodiments;

FIG. 2A illustrates an example of a digital twin simulation for a controlled environment and system;

FIG. 2B illustrates an example of propagation of data through the digital twin simulation;

FIG. 2C illustrates an example of extracting virtual sensor data from the digital twin simulation;

FIG. 3 illustrates an example hardware device for implementing various embodiments;

FIG. 4 illustrates an example of a portion of a neural network for implementing a digital twin simulation according to various embodiments;

FIG. 5 illustrates an example of a method for propagating state data through a digital twin simulation; and

FIG. 6 illustrates an example of a registry for available virtual sensors in a system.

### DETAILED DESCRIPTION

The description and drawings presented herein illustrate various principles. It will be appreciated that those skilled in the art will be able to devise various arrangements that, although not explicitly described or shown herein, embody these principles and are included within the scope of this disclosure. As used herein, the term, “or,” as used herein, refers to a non-exclusive or (i.e., and/or), unless otherwise indicated (e.g., “or else” or “or in the alternative”). Additionally, the various embodiments described herein are not necessarily mutually exclusive and may be combined to produce additional embodiments that incorporate the principles described herein.

Conventional control systems and sensor-driven software architectures suffer from multiple technical limitations that constrain scalability, computational efficiency, and fidelity of system state estimation. These limitations become particularly acute in complex physical environments, such as buildings, industrial systems, or other multi-zone systems, where system state propagates across space and time according to physical laws.

One technical problem in the current art is the over-reliance on physical sensors to obtain system state. Existing approaches typically require dense deployment of hardware sensors to approximate full observability of a system. This results in increased hardware cost, power consumption, network bandwidth utilization, and controller processing overhead. Even with such deployment, sensor placement is often sparse, fixed, and suboptimal, leaving large portions of the system unobserved or poorly observed. Current systems lack an effective computational mechanism to infer missing state values with sufficient physical realism and numerical stability.

Another technical problem is that prior approaches which attempt to infer or estimate unmeasured values typically rely on static heuristics, simple interpolation, or purely data-driven machine learning models. Such techniques fail to accurately model bidirectional, multi-path propagation of state through interconnected physical structures. In particular, conventional neural networks are generally organized as feed-forward or layered architectures that do not reflect the omnidirectional, cyclic, and physically constrained interactions present in real-world systems. As a result, these systems either produce inaccurate estimates or require excessive computational resources to retrain models when system configurations change.

Yet another technical problem is inefficient use of computing resources. Prior art systems often recompute entire models or simulations whenever new sensor data is received, even when changes are localized. This leads to unnecessary processor utilization, increased memory pressure, and higher latency, particularly in real-time or near-real-time control environments. Such inefficiencies degrade overall computer performance and limit system scalability.

A fourth technical problem arises from the inability of prior systems to dynamically define, manage, and expose virtual sensing points through standardized computing interfaces. Existing solutions generally hard-code sensor logic or derived values, making it difficult to create new logical sensors, derived metrics, or time-shifted queries without modifying core application logic. This rigidity increases software complexity and reduces reliability.

The present embodiments address the foregoing technical problems through a concrete, computer-implemented architecture that improves the functioning of computing systems used for simulation, control, and sensor data processing.

First, the disclosed embodiments replace the need for dense physical sensor deployment by introducing a digital twin simulation that propagates real sensor measurements through a structured computational model of the physical system. By encoding physical adjacency, material properties, and transfer behavior into an omnidirectional neural network, the system enables generation of virtual sensor values at locations where no physical sensor exists. This reduces hardware dependencies while increasing observability, thereby lowering I/O load, reducing network traffic, and improving overall system efficiency.

Second, the use of physics-based transfer functions embedded within neuron activation functions solves the deficiencies of purely data-driven or heuristic models. Each neuron represents a concrete physical or logical component, and each activation function performs a mathematically defined transformation grounded in physical behavior. This architecture enables bidirectional propagation, multi-input resolution, and iterative convergence, which cannot be achieved by traditional feed-forward neural networks. As a result, the computer executes fewer corrective recalculations and maintains higher numerical stability, improving processor efficiency and simulation accuracy.

Third, the virtual sensor registry and associated API instructions introduce a programmable, runtime-configurable interface for exposing system state. Virtual sensors can be defined, transformed, authorized, and queried without modifying the underlying simulation code. This modular architecture reduces software complexity, improves maintainability, and allows computers to serve a wider range of downstream applications with fewer duplicated computations.

Importantly, the present embodiments are not capable of being performed in the human mind. The simulation involves maintaining and updating large-scale graph data structures, executing iterative numerical propagation across interconnected nodes, storing multi-dimensional state values and time-based curves in memory, and performing continuous machine learning-based tuning using gradient descent or auto-differentiation. These operations require high-speed processors, non-transitory memory, and specialized execution flows that are fundamentally beyond mental processes or pencil-and-paper calculations.

Various embodiments described herein relate to systems and methods for generating virtual sensor values using a digital twin of a physical environment. The application describes modeling a system, such as a building or other controlled environment, in which real sensor measurements are received at certain locations and used as inputs to a computational representation of the system. The digital twin represents physical and logical components of the environment and enables simulation of system state across locations where physical sensors may or may not be present.

In various embodiments, the digital twin is structured as a network of interconnected computational elements, referred to as neurons, each corresponding to a component of the modeled environment, such as a zone, wall, sensor, or external influence. Each neuron stores one or more state values and applies an activation function, which may have one or more equations, to propagate state between connected neurons. The activation functions may model physical relationships between components, allowing state values to flow through the digital twin in a manner consistent with the modeled environment.

Further embodiments describe extracting virtual sensor values from the digital twin through introspection of neuron state. A virtual sensor may correspond to a particular neuron and value type, or may apply one or more transformation functions to generate derived values from stored state. The application also describes mechanisms for managing and exposing virtual sensors through a registry and application programming interface, allowing external applications to request and receive virtual sensor data generated by the digital twin.

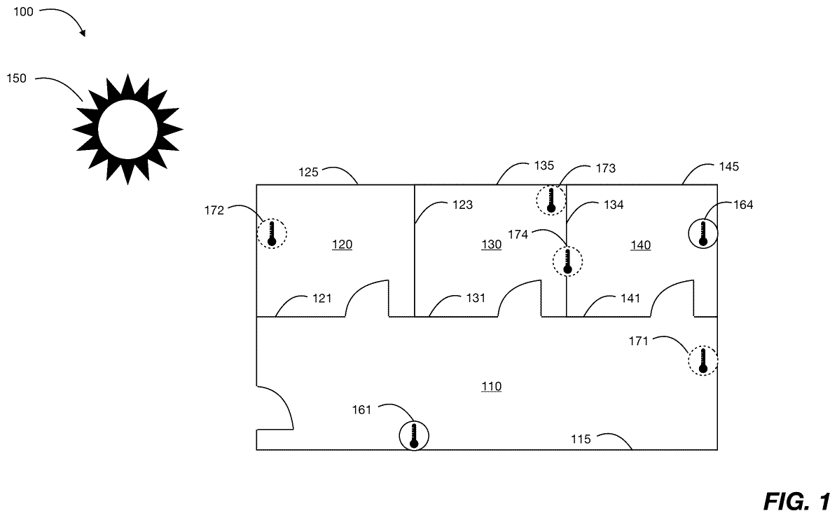

FIG. 1 illustrates an example of an environment 100 for operation of various embodiments. The environment 100 as shown may be a building in which a heating, ventilation, and air conditioning (HVAC) system is deployed and controllable to manage the temperature of the various zones. As used herein, an “HVAC system” refers to any system that includes equipment for raising the temperature of an environment (“heating”), lowering the temperature of an environment (“cooling”), or directing movement of air in an environment (“ventilation”). It will be apparent that the techniques described herein may be applicable to other environments and systems deployed therein. For example, the techniques described herein may be implemented in the context of controlling a lighting system, an automated irrigation or other agricultural system, a power distribution system, a manufacturing or other industrial system, or virtually any other system that may be controlled. Further, the techniques may be applied outside of controlled systems in virtually any environment where sensor data might be used or useful.

As shown, the environment includes a building with four zones 110, 120, 130, 140 defined by the exterior and interior walls of the building. Each zone 110, 120, 130, 140 may define a volume of air that is to be treated, from the HVAC system point of view, as a single area to be controlled. Thus, for example, zone 110 may be controlled to one temperature while zone 120 may be controlled to a different temperature. While the illustrated embodiment shows a 1:1 correspondence between rooms and zones, this may not always be the case. A single zone may be defined encompassing multiple rooms or a single room (especially a very large room) may encompass multiple zones for HVAC purposes.

As noted, the building includes walls (as most do). Zone 110 is surrounded on three sides by an exterior wall 115 and on the fourth side, an interior wall 121 separating it from zone 120, an interior wall 131 separating it from zone 130, and an interior wall separating it from zone 140. Similarly, zone 120 is surrounded by an exterior wall 125, interior wall 121, and an interior wall 123 separating it from zone 130. Zone 130 is surrounded by an exterior wall 135, interior wall 131, interior wall 123, and an interior wall 134 separating it from zone 140. Zone 140 is surrounded by an exterior wall 145, interior wall 141, and interior wall 134.

While the zones 110, 120, 130, 140 are viewed as separate items for control, in the real world they are usually not independent from each other in the context of HVAC systems. State (particularly heat, but also other environment factors such as humidity, particulate matter, and abstracted concepts such as comfort as will be explained in greater detail blow) is transferred between zones 110, 120, 130, 140. The transfer can occur simply by airflow (through doors, vents, or other open spaces) or by transfer through other intermediate items such as walls. For example, if zone 120 is particularly hot, it may heat up wall 121, which in turn may radiate heat into zone 110, and so forth. Thus, state tends to propagate through the environment 100 according to various physical principles.

Some environments and systems may be closed systems, unaffected by external forces, while others may be open, and subject to the effects of at least one external force. In the example environment 100, the HVAC state is affected by the state outside the building-the weather 150. In the context of temperature, the ambient temperature, ground temperature, sunshine, and so forth, may all act to heat the exterior walls 115, 125, 135, 145 which may then radiate heat into the zones 110, 120, 130, 140. Similarly, when the weather 150 is relatively cold, heat may radiate out of the building through the exterior walls 115, 125, 135, 145. Other aspects of state in the zones 110, 120, 130, 140 may be affected by the weather 150 or other external forces as well.

The environment includes two real temperature sensors 161, 164, denoted in solid lines. Real sensor 161 may measure a temperature near the south side of zone 110, while real sensor 164 may measure a temperature near the east side of zone 140. These sensors 161, 164 may be in communication with or otherwise readable by a control system (not shown) that controls various HVAC equipment (not shown) to manage the temperature and other state of the zones 110, 120, 130, 140. It will be apparent that the sensors 161, 164 or other sensors (not shown) may be capable of measuring and making available other state measurements that may be useful for the control system in making decisions as to how the HVAC system should be controlled.

According to various principles and techniques described herein, multiple virtual sensors 171, 172, 173, 174 are “disposed” within the environment, denoted in dashed lines. In other words, while physical sensors are not installed at these locations, the techniques described herein are utilized to enable virtual sensor readings at the shown locations: a virtual sensor 171 for reading the state of zone 110 at a different location from physical sensor 161, a virtual sensor 172 for reading the state of zone 120, a virtual sensor 173 for reading the state of zone 130, and a virtual sensor for reading the state inside interior wall 134. Such virtual sensor readings may be made available to the control system for making more informed decisions about how to control the HVAC system or may be made available to other applications (e.g., via an application programmer interface or “API”) such as a downstream program that estimates energy efficiency of the control system. In some embodiments, a non-sensor display device may be installed in the environment that displays the virtual sensor reading for occupants. For example, a small display device having a form factor similar to a thermostat may be installed on the west wall of zone 120 to output the reading of virtual sensor 172.

By providing for the operation and use of virtual sensors such as virtual sensors 171, 172, 173, 174, various embodiments provide control systems and other applications with additional data without drastically increasing system install and operation costs by requiring additional physical sensors. Put another way, various embodiments put the available ground truth data to better use and extract additional information than is possible through conventional techniques, thereby improving the operation of control systems and other downstream applications. Furthermore, the virtual nature of the sensors according to the techniques described herein provide a high degree of flexibility, enabling the definition of new virtual sensors on the fly as needed, rather than physical sensors that are designed into a system and installed a priori based on projected need. Various additional benefits of the techniques described herein will be apparent in view of this disclosure.

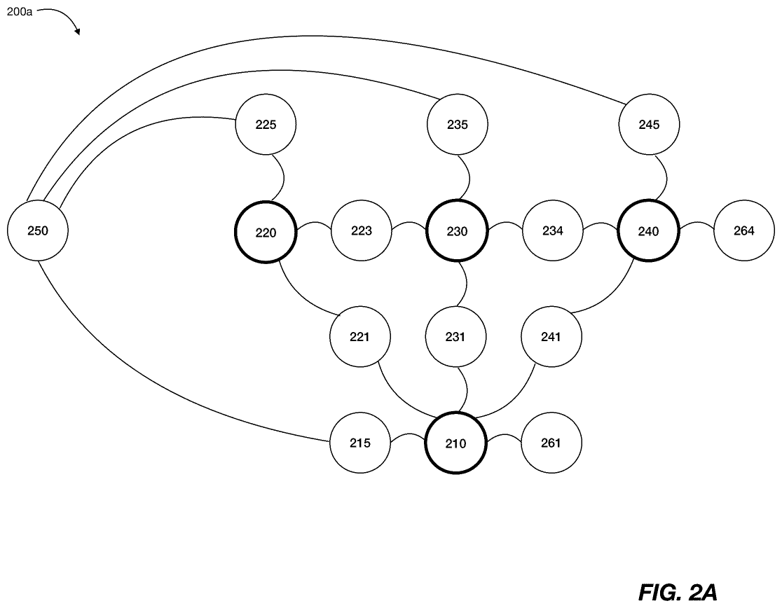

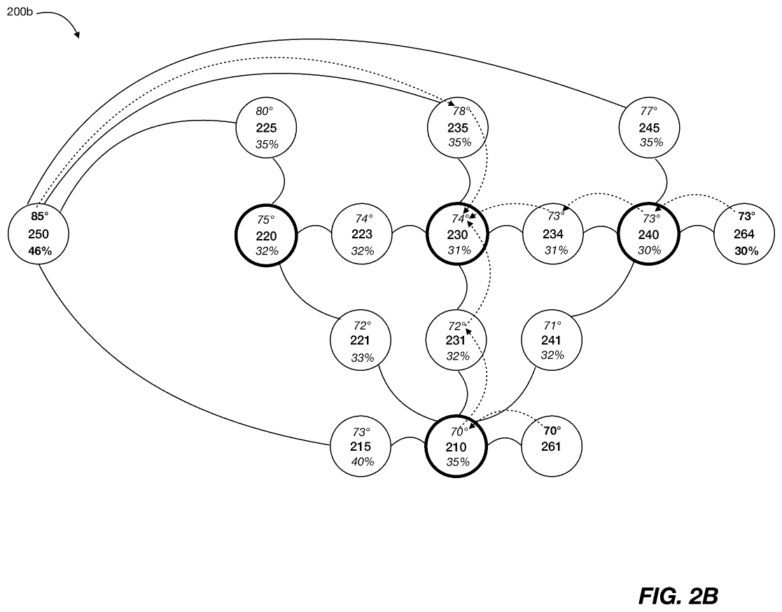

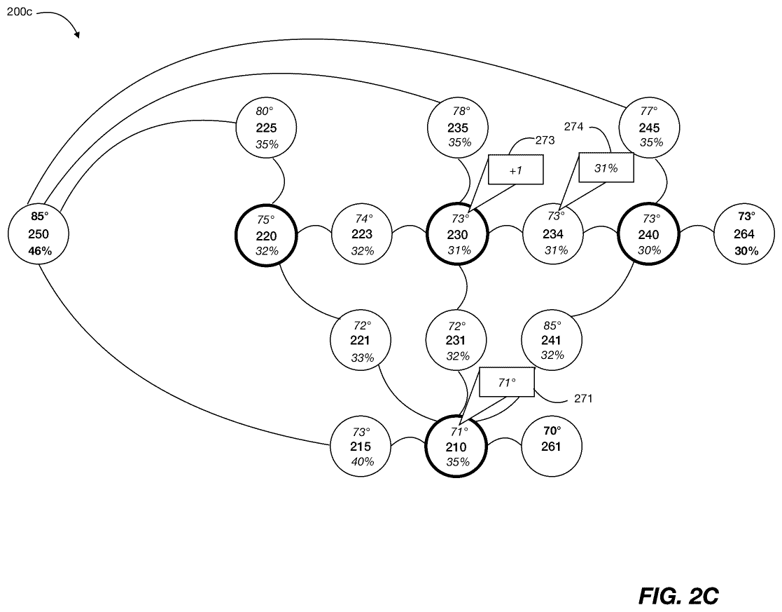

FIG. 2A illustrates an example of a digital twin simulation 200a for a controlled environment and system. The digital twin simulation 200a may correspond to the example embodiment 100 of FIG. 1. As shown, the digital twin simulation 200a is formed as a type of neural network, though various alternative approaches may be used to form a digital twin simulation and modifications for enabling the techniques described herein will be apparent.

The digital twin simulation 200a models the various elements of the example environment 100 as individual neurons. For example, neurons 210, 220, 230, 240, shown in bold, may represent zones 110, 120, 130, 140, respectively. Neurons 221, 231, 241, 223, 234 may represent the interior walls 121, 131, 141, 123, 134, respectively. The various connections between the zone neurons 210, 220, 230, 240 and the interior wall neurons 221, 231, 241, 223, 234 represent the ability for state to be transferred from one neuron-represented element to another. For example, heat can be transferred from zone 110 to interior wall 121, and therefore a connection exists between neuron 210 and neuron 121; as such the activation functions of neuron 210 and neuron 121 may pass information via this connection.

At this point, it may be apparent that the neural network implementing the digital twin simulation 200a may not operate according to traditional neural network principals. Traditional neural networks include a directionality-information is provided to an input layer of neurons which, according to internal activation functions, process and feed information forward through a sequence of ordered hidden layers until eventually the information can be read from a layer of one or more output neurons. In the illustrated embodiment of digital twin simulation 200a, the various neurons may be bidirectional: for example, neuron 210 may, through its activation function, pass state information to neuron 221 while neuron 221 may, through its activation function, pass state information back to neuron 210. This may provide an accurate simulation of an environment and system such as environment 100, where state does not always have a unidirectional flow. In the context of HVAC, hot and cool air from multiple sources flow and intermingle across multiple and potentially changing paths.

Furthermore, the neural network may be heterogenous neural network, employing different activation functions in different neurons. These activation functions may be physics-or other science-based functions for modeling the flow of heat energy, fluid, electricity, data packets, or other quanta from neuron to neuron. Additional training may then further refine the operation of these activation functions from the ideal, textbook functions to more closely match the observed system operation. This may stand in contrast to traditional neural networks, which employ homogeneous activation functions that may be trained entirely based on training data such as retrospective data or live system observations.

Continuing to describe the neurons of the digital twin simulation 200a, neurons 215, 225, 235, 245 may represent the exterior walls 115, 125, 135, 145 while neuron 250 may represent the external forces 150 such as the current or forecasted weather. Neurons 261, 264 may represent the physical temperature sensors 161, 164, respectively.

As described above, the shown connections may represent the ability of any given neuron to propagate information, via an internal activation function, to another neuron. The activation function may be determined, at least in part, by a physics-based transfer function. For example, heat transfer from a zone to a wall, from a wall to a zone, or from external forces to a wall may be described by a convective heat transfer function known in physics, which may in turn depend on various coefficients specific to the environment such as surface area and convective heat transfer coefficient (which may be determined by, e.g., the material and layers of the wall). Thus, the physics of the environment can be modeled among the neurons of the digital twin simulation 200a by gathering additional information describing the embodiment beyond just temperature.

Further, in some embodiments, the physics modeling need not be performed exactly correctly at the outset. In some such embodiments, a separate process may continue to observe the environment 100 and compare it to the predictions of the digital twin simulation 200a, and make adjustments when the two diverge. For example, assume the transfer coefficient/material is initially not correctly set for the interior wall neuron 241. The digital twin simulation 200a consistently predicts that heat introduced in zone 110 will propagate through the wall 141 and equalize the temperature in zone 140 within 30 minutes, but by watching the values of the temperature sensors 161, 164, it is seen that this process actually takes 1 hour. The system may adjust the coefficients to better model the actually observed behavior of the environment over time. This feature may address the potential issue of initially incorrectly modeled physics as well as changes to physics over time (e.g., degradation of the wall or opening and closing of doors). In various embodiments, this learning may be implemented using gradient descent and auto-differentiation, to ensure that the neurons of the digital twin simulation 200a are continually tuned to match the actual observed environment and system behavior.

As another example, the physics-based transfer function from the sensor neuron 261 to zone neuron 210 may be an absolute passthrough, because the sensor 161 value is taken to be the true temperature of the zone 110. Alternatively, the activation function may still modify the temperature value when propagated from neuron 261 to neuron 210 because it may be known or the system may learn (e.g., in a manner similar to that disclosed above) that the sensor 161 is disposed in a relative hot or cold spot compared to the average of the full zone 110.

Simulation using the physics-based transfer function may be performed through multiple activations of the neurons, for example, over each of a series of time steps. For example, each activation function may simulate a change in state over only a one-second period of time. Thus, to predict the state one minute in the future, the neurons may be simulated sixty times, once for each second in the minute under simulation. It will be apparent that other time steps may be possible, and that activation functions of differing time granularities may be employed.

FIG. 2B illustrates an example of propagation of data through the digital twin simulation 200b. The digital twin simulation 200b may correspond to the digital twin simulation 200a at a particular time when known temperatures are to be propagated through the neurons. As shown, each neuron carries an internal temperature value. As shown in bold, sensor neurons 261, 264 have actual temperature readings 70 and 73 degrees respectively. These values may be received from the real world sensors 161, 164. Similarly external forces neuron 250 has a bold known temperature value, 85 degrees, which may be obtained by accessing weather data via the Internet, from a sensor disposed outside, or from another source. Using these three known values, temperatures can be propagated through the various activation functions of the digital twin representation 200b, to simulate the likely temperatures at different parts of the environment 100. To illustrate, an example of propagation of the three known temperatures to the zone neuron 230 will now be described.

Starting with external force neuron 250, a temperature of 85 is transferred to exterior wall neuron 235, heating it to 78 degrees at a particular time being simulated. This 78 degrees is then passed forward, according to another activation function to zone neuron 230.

Meanwhile, sensor neuron 264 passes its temperature of 73 degrees through its activation function to zone neuron 240, which is passed through another activation function to interior wall neuron 234, which then passes the value through yet another activation function to zone neuron 230. In this case, the activation functions appear to have equalized with the temperature remaining 73 degrees through each of these hops.

Next, the 70 degree reading is similarly passed through a series of activation functions to zone neuron 210, interior wall neuron 231, and to zone neuron 230, rising from 70 degrees to 72 degrees at the interior wall neuron 231. Zone neuron 230, receiving multiple temperatures from different neurons, may then combine the temperatures to come to a single estimated temperature for the real world zone 130. For example, physics modeling may be used internally to the neuron 230 itself to determine the relative contribution of each incoming temperature to the overall temperature of the zone 130. For example, in some such embodiments, a physics-based combination of neighboring temperatures using heat transfer equations, resistance, capacitance, and other relevant values descriptive of the system to produce a single temperature attributable to the neuron. Alternatively, the neuron 230 may compute an average or weighted average of all provided temperatures.

It should be understood that the foregoing example is, in some respects, a simplification. For example, while three paths are described, state may enter the zone neuron 230 from additional paths. For example, external force neuron 250 may transfer state to exterior wall neuron 225, to zone neuron 220, to interior wall neuron 223, to zone neuron 230, thereby modeling the additional heat entering zone 130 from zone 120. Further, state in zone neuron 230 may itself propagate and affect other neurons. For example, the 74 degrees may pass from zone neuron 230 to interior wall 231 to zone neuron 210, modeling the heat that would be transferred in that direction. It will be apparent that this example system, as well as other alternative environments and systems, include multiple interdependent elements, which may be modeled according to an omnidirectional neural network or other type of digital twin representation.

It will also be appreciated that, while the various examples are described in the context of predicting one or more singular state values at a particular point in time, these techniques may also be applied to simulating such state values over time, e.g., as a value curve. For example, if the weather were to suddenly change and the external force node 250 dropped to 70 degrees, the simulation 200b in some embodiments may not immediately propagate this value to drop exterior wall node 225 from 80 to 70 degrees; in the real world, it would take some time for the heat stored in the external wall 125 to dissipate into the outside area. Instead, the digital twin simulation 200b may simulate the change in temperate over time as a value curve which may then then propagated forward as described above through activation functions to simulate value curves at each of the other nodes. Similarly, a sensor value may be propagated through the digital twin simulation 200b by propagating time-series value curves though the neurons and activation functions. In some such embodiments, this may be achieved by recording simulated values at each time step over the course of a simulation.

Further, as noted above, the digital twin simulation 200b may handle more than one value type. For example, as shown at the bottom of each neuron, the digital twin simulation 200b may also track a humidity through the environment 100. As shown, the external humidity may be known (e.g., from current or forecast weather data) to be 46% and added to external force neuron 250. The real sensor 164 may also be a humidity sensor and may therefore impute a humidity value of 30% to the sensor neuron 264. Real sensor 161, on the other hand, may not be equipped to sense humidity and therefore may provide no humidity value to sensor neuron 261. From here, the humidity may be propagated through the digital twin simulation 200b in a manner similar to that described above with respect to temperature: physics-based transfer function describing ideal propagation of humidity in an environment tuned to better match according to observations of the real environment being modeled may serve as activation functions between each of the neurons, allowing the humidity measurements to propagate through the digital twin simulation 200b.

In some such embodiments, even though the real sensor 161 may not provide a humidity value, it may still have a role to play in propagation of humidity values through the digital twin representation. This is because temperature plays a role in humidity as well. The inverse relationship between temperature and humidity may also be modeled as a physics-based transfer function and used as part of the activation functions between the neurons. Thus, as can be seen, the relatively lower 70 degree temperature provided from sensor neuron 261 to zone neuron 210 may inform the humidity value of that same zone neuron 210, leading to a relatively higher humidity of 35% than the other zone neurons 220, 230, 240. In a similar manner, virtually any value can be propagated through the digital twin representation 200c to provide like and disparate value types if there is some relationship between the value types that can be captured in the physics-based transfer function.

There may be some applications where the relationships between different value types are not derived from physics but some other base set of rules. For example, the field of chemistry may provide the basis for a digital twin simulation that models chemical reactions. In the context of applications (or portions thereof) that are not ultimately grounded in physics-based relationships, the term “physics-based transfer function” will be understood (when used in such context) to encompass those functions expressing the relationship between values, even though such formula may not be actually expressive of physical principles.

FIG. 2C illustrates an example of extracting virtual sensor data from the digital twin simulation 200c. The digital twin simulation 200c may correspond to the digital twin simulation 200b at a time after the temperature values have been propagated and are ready to be used.

In some embodiments and circumstances, extracting a virtual sensor value may be as simple as reading a value from the appropriate neuron. As shown in this simple example, to extract a value 271 for virtual sensor 171, one need only read the value already stored in the neuron 210 as a result of propagation described with respect to digital twin 200b, yielding a virtual sensor reading of 71 degrees. Thus, as can be seen, a virtual sensor can be defined on the fly at any of the neurons (and, therefore, the physical structure corresponding to that neuron) of the digital twin simulation 200c simply by reading the values from the neuron.

As another example, sensor 174 may be configured as a humidity sensor disposed within the interior wall 134. Again, because humidity values have already been propagated through the digital twin representation 200c as described above, extracting this value is a simple matter of reading the value of 31% from the interior wall neuron 234. As can be seen, the techniques described herein enable the deployment of virtual sensors in more uses than real sensors are typically used. Here, physical humidity sensors would rarely, if ever, be installed in the interior of a wall. But, because the interior wall 134 has been modeled, the virtual humidity sensor 174 can be defined to watch the interior humidity if and when there is interest in this information.

In some embodiments, virtual sensors may be deployed that extract derived values for use in downstream applications. For example, as is known in the field of HVAC control, there are various formulas for calculating comfort levels (e.g., Fanger's PMV comfort formulas). For the purposes of the present example, the digital twin simulation 200c uses a simple comfort formula based on temperature and humidity that returns a value between −3 and +3. Such derivation may be performed at the time of extraction from a virtual comfort sensor, such as sensor 173. Upon extraction 273, the system reads the temperature and humidity values from the zone node 230, applies the formula these values to generate a comfort value of +1, and provides this value to the control system or other downstream application. In this way, a virtual sensor can be deployed for any derived value using values from the attached neuron at the present or future times, or even using the same values from adjacent or other neurons.

As noted above, in some embodiments, values may be propagated through the digital twin representation 200b as time-dependent value curves, capturing the values over time. These value curves may include previous values or future predicted values. In such embodiments, to extract a present value, the extraction may simply read the value from the portion of the value curve associated with the present time. It will be apparent that the presence of the value curve may enable additional types of virtual sensors. For example, a virtual sensor may be configured to provide value readings at a different time than present (e.g., the temperature at 3:00 pm today, the humidity 2 hours ago, the temperature 30 minutes from now, etc.). As another example, value curves may enable virtual sensors that derive from rates of change over time (e.g., the temperature change over the past 2 hours, the current acceleration in temperature change, etc.). As yet another example, virtual sensors may be configured to output relevant times by querying the value curve for when a condition was or will be met (e.g., how long until the comfort level reaches 0, what time will the temperature next reach 70 degrees). Various other virtual sensor types will be apparent in view of the present disclosure.

Returning to zone neuron 210, it is worth noting that its temperature value is not exactly the same as the sensor neuron 261 for the physical sensor 161 installed in the zone 210. This may be explained in physical world terms by the installation of the sensor 161 in a relative cold spot compared to the overall temperature of the zone. In the context of the digital twin simulation 200c, it can be explained by the combined effects of propagating temperatures from the adjacent neurons: not only the 70 degrees from the sensor neuron 261, but also the higher temperatures from wall neurons 215,221,231,241. Thus, this corrective behavior may be emergent from the normal operation of the propagation of values through the digital twin simulation 200c.

In some embodiments, the behavior can be designed into the system by splitting the neuron for a single item into two or more neurons, and adding a connection and activation function modeling the propagation of values between the two sub-sections of the real world structure. For example, zone neuron 210 may be split into two connected neurons representing the west half of zone 210 and the east half of zone 210. The connection between these two replacement neurons may be associated with activation functions that model the flow of air or propagation of temperature across an open space in full fluid communication. Such a change may lead to other changes such as, for example, the splitting of the exterior wall neuron 215 into two connected neurons, representing the two portions of exterior wall 115 that are adjacent the two subdivisions of zone 110, respectively.

As another example, an interior wall neuron 223 may be split into multiple connected neurons that model the different layers of the wall, including differing dimensions and material types. Such a change may improve the fidelity of the simulation at the cost of additional processing resources. Thus, the techniques described herein offer the creator a degree of design choice, trading off fidelity and granularity for efficiency, to find the optimum simulation that suits the identified applications. As application requirements change, the approach offers flexibility to redefine the digital twin simulation as desired to rebalance these changes.

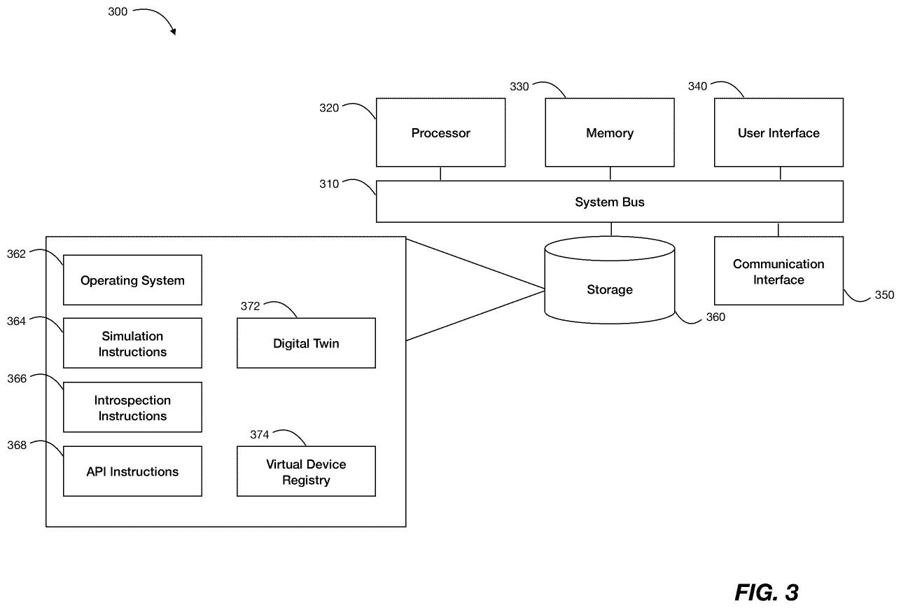

FIG. 3 illustrates an example hardware device 300 for implementing various embodiments. As shown, the device 300 includes a processor 320, memory 330, user interface 340, communication interface 350, and storage 360 interconnected via one or more system buses 310. It will be understood that FIG. 3 constitutes, in some respects, an abstraction and that the actual organization of the components of the device 300 may be more complex than illustrated.

The processor 320 may be any hardware device capable of executing instructions stored in memory 330 or storage 360 or otherwise processing data. As such, the processor 320 may include a microprocessor, field programmable gate array (FPGA), application-specific integrated circuit (ASIC), or other similar devices.

The memory 330 may include various memories such as, for example L1, L2, or L3 cache or system memory. As such, the memory 330 may include static random access memory (SRAM), dynamic RAM (DRAM), flash memory, read only memory (ROM), or other similar memory devices. It will be apparent that, in embodiments where the processor includes one or more ASICs (or other processing devices) that implement one or more of the functions described herein in hardware, the software described as corresponding to such functionality in other embodiments may be omitted.

The user interface 340 may include one or more devices for enabling communication with a user such as an administrator. For example, the user interface 340 may include a display, a mouse, a keyboard for receiving user commands, or a touchscreen. In some embodiments, the user interface 340 may include a command line interface or graphical user interface that may be presented to a remote terminal via the communication interface 350 (e.g., as a website served via a web server).

The communication interface 350 may include one or more devices for enabling communication with other hardware devices. For example, the communication interface 350 may include a network interface card (NIC) configured to communicate according to the Ethernet protocol. Additionally, the communication interface 350 may implement a TCP/IP stack for communication according to the TCP/IP protocols. In devices 300 that operate as a device controller, the communications interface 350 may additionally include one or more direct wired connections to such controlled devices or connections to separate I/O modules (not shown) providing such connections. In applications where the device 300 is deployed in the context of an HVAC system, the communications interface may communicate according to an appropriate protocol such as BACnet. Various alternative or additional hardware or configurations for the communication interface 350 will be apparent.

The storage 360 may include one or more machine-readable storage media such as read-only memory (ROM), random-access memory (RAM), magnetic disk storage media, optical storage media, flash-memory devices, or similar storage media. In various embodiments, the storage 360 may store instructions for execution by the processor 320 or data upon with the processor 320 may operate. For example, the storage 360 may store a base operating system 361 for controlling various basic operations of the hardware 300.

The storage 360 may store a digital twin 372 that represents one or more environments or systems to be simulated. In various embodiments, the digital twin 372 may be formed as an omnidirectional neural network as described above. As such, the digital twin may store a collection of descriptions of neurons and connections therebetween, including internal values (e.g., temperature and pressure) and activation functions. In various alternative embodiments, different types of digital twin constructions and formats may be used. Various digital twin characteristics necessary or useful for implementing the techniques described herein will be apparent such as, for example, the ability to propagate values according to physics-based transfer functions, the ability to define adjacency of the real world elements to be represented, and the ability to read values or otherwise introspect the digital twin 372 at desired locations.

Simulation instructions 364 may be included to operate on the digital twin 372. For example, the simulation instructions 364 may propagate values through the digital twin 372 as described above. As another example, the simulation instructions 364 may use the digital twin 372 to simulate the state of an environment or system over time after one or more possible control actions are taken. Such a simulation may help to identify a desired set of control actions to be taken with respect to a controlled system to achieve a desired state. Various additional uses or implementations for simulation instructions 364 will be apparent.

Introspection instructions 366 may be included to query or otherwise discern information from the digital twin 372. For example, where a virtual sensor is configured to simply read a value already stored in the digital twin 372, the introspection instructions 366 may include instructions for locating the appropriate part of the digital twin (e.g., the intended neuron) and extracting the desired value(s) therefrom. The introspection instructions 366 may additionally include instructions for reading such values from a time curve as previously described. The introspection instructions 366 may additionally include instructions for applying one or more transform functions to create one or more derived values, as previously described. In some embodiments, the introspection instructions 366 may be able to execute queries against the digital twin 372. For example, the introspection instructions 366 may be able to retrieve “the temperatures of all interior walls” or “any zone with a comfort that is not 0 .” Such functionality may be enabled or facilitated when the digital twin 372 is organized according to a well-defined ontology.

API instructions 368 may be included in embodiments where the device 300 provides virtual sensor data to one or more other devices that may implement downstream applications. For example, such other devices (not shown) may request creation of a new virtual device or access to an existing virtual device by sending a message via the communications interface 350 to be processed by the API instructions 368. The API instructions 368 may perform authorization and authentication of such downstream devices against a virtual device registry 374 that tracks API keys and established virtual devices, and then obtain, from the introspection instructions 366, the requested values, and serve the requested values via communication interface 350 to the requesting devices. Serving of such requested values may be done on a pull basis (e.g., whenever explicitly requested) or on a push basis (e.g., whenever the value changes or on a periodic basis).

It will be apparent that various information described as stored in the storage 360 may be additionally or alternatively stored in the memory 330. In this respect, the memory 330 may also be considered to constitute a “storage device” and the storage 360 may be considered a “memory.” Various other arrangements will be apparent. Further, the memory 330 and storage 360 may both be considered to be “non-transitory machine-readable media.” As used herein, the term “non-transitory” will be understood to exclude transitory signals but to include all forms of storage, including both volatile and non-volatile memories.

While the hardware device 300 is shown as including one of each described component, the various components may be duplicated in various embodiments. For example, the processor 320 may include multiple microprocessors that are configured to independently execute the methods described herein or are configured to perform steps or subroutines of the methods described herein such that the multiple processors cooperate to achieve the functionality described herein, such as in the case where the device 300 participates in a distributed processing architecture with other devices which may be similar to device 300. Further, where the device 300 is implemented in a cloud computing system, the various hardware components may belong to separate physical systems. For example, the processor 320 may include a first processor in a first server and a second processor in a second server.

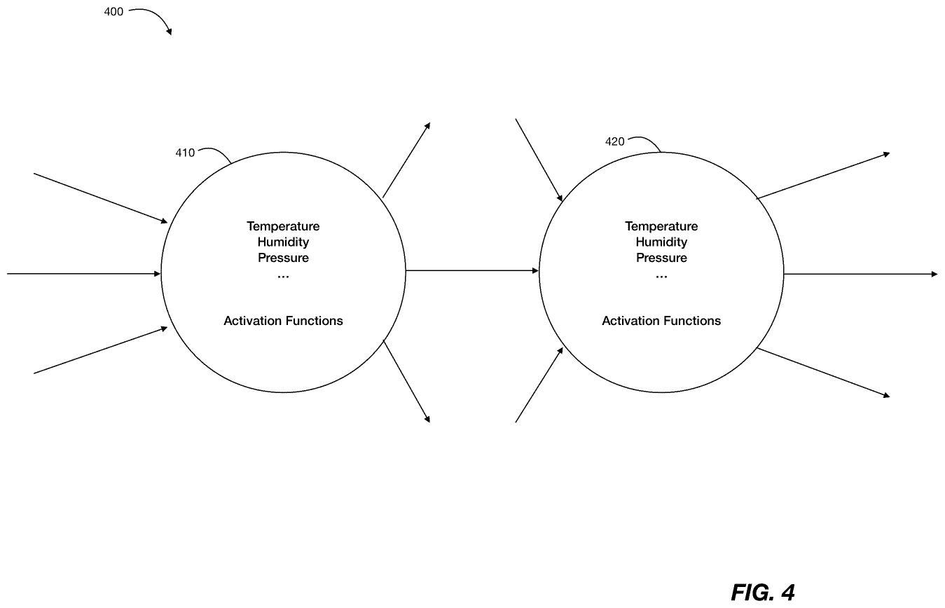

FIG. 4 illustrates an example of a portion of a neural network 400 for implementing a digital twin simulation according to various embodiments. The neural network portion 400 may correspond, for example, to a portion of the digital twin representation 200a-c. As shown, the neural network portion 400 includes two neurons, 410, 420 with a connection therebetween. Further, the neurons may include multiple additional incoming and outgoing connections (illustrated as arrows) to other neurons (not shown). While the connections are shown as unidirectional arrows, in other embodiments, the connections may be bidirectional, allowing for information to flow information to flow in both directions: from neuron 410 to neuron 420 as well as from neuron 420 to neuron 410.

The neurons 410, 420 are both configured to store some state values. In this embodiment where the neural network simulates an HVAC environment, the neurons 410, 420 store values such as temperature, humidity, and pressure. The values may be expressed as singular values, time-based value curves, or any other format useful for holding a state value.

The neurons 410, 420 are also both configured to store at least one activation function. As noted above, the activation function may be (or include as a component) a physics-based transfer function that models how one or more of the state values propagate through the real world element that the neuron 410, 420 represents. For example, with respect to temperature, the activation functions may include heat transfer functions. The physics-based transfer function may take into account properties of the real world element (e.g. in the case of a heat transfer function, material and surface area. These properties (not shown) may be stored separately in the neuron 410, 420 or baked in to the physics-based transfer function. The physics-based transfer function may be an ideal or textbook function or may be tuned away from ideal or textbook based on observations from the environment or system being modeled. For example, gradient descent or auto-differentiation may be employed to tune the aforementioned properties or one or more coefficients inserted into the ideal function for the purpose of such tuning. In some embodiments, the neuron 410, 420 may start with no function or a minimal function (e.g., a pure passthrough of state) and be left to discover through machine learning (e.g., gradient descent or auto-differentiation) the applicable physics-based transfer function for the state values in each neuron.

During propagation, an activation function may be applied to the relevant state values stored in the neuron 410 to produce a value to pass forward to neuron 420 via the connection. In some embodiments, an activation function for a particular state value (or set of state values) may be applied to all outgoing connections, and as such the produced value may be additionally passed over other outgoing connections. In other embodiments, a different activation function may be associated with each different outgoing connection.

Upon receiving a value during propagation from neuron 410, neuron 420 may use the received information to update the relevant internal state values. In some embodiments, the received value may replace the previously-stored internal state values or may modify the previously-stored internal state values according to an internal rule. In some embodiments, the neuron may receive during one propagation multiple incoming values from other neurons including neuron 410. In such embodiments, the neuron 420 may use an internal rule to combine all received values to update the internal state values. Then neuron 420 may then proceed to propagate values forward through its outgoing connections according to its own activation function(s).

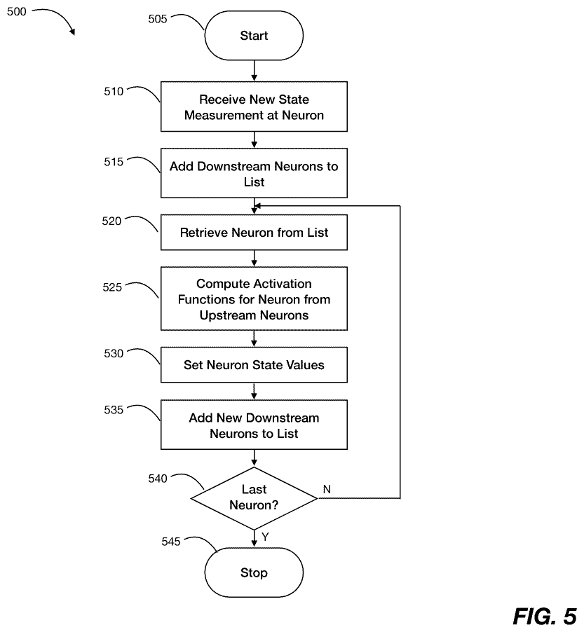

FIG. 5 illustrates an example method 500 for propagating real sensor values through a digital twin simulation in order to generate one or more virtual sensor values. In the illustrated embodiment, state propagation is performed using a pull-based mechanism in which a neuron determines its updated state value by retrieving transformed values from one or more upstream neurons. In other embodiments, a push-based mechanism may be used in which a neuron applies its activation function and transmits resulting values to downstream neurons. Both pull-based and push-based propagation mechanisms are within the scope of the disclosed embodiments and may be used interchangeably or in combination.

The method 500 may correspond to the simulation instructions 364 and may begin in step 505 when the method 500 determines that a propagation should be performed. This determination may occur in response to receipt of a new real sensor value, receipt of a request for a virtual sensor value from an application, expiration of a simulation time step, or any combination thereof. In step 510, the method 500 receives a real sensor value measured by a sensor device at a physical location within the system. The received real sensor value may be associated with a corresponding simulated location in the digital twin and stored as a state value at a neuron representing that location. For example, step 510 may involve reading a real temperature or other sensor value from sensor 161 or sensor 164, and attributed to neuron 261 or neuron 264, respectively.

In step 515, the method 500 identifies all neurons that are connected downstream from the current neuron and add them to a running list of neurons to be processed. In some embodiments, the method 500 may identify all neurons to which the current neuron is connected, all such neurons that have not already been processed, or all such neurons not already on the running list. For example, if the current neuron is neuron 261, the method 500 may add neuron 210 to the list. In some embodiments, the method ensures that neurons are added to the list only once per propagation cycle.

In step 520, the method 500 begins to iteratively process and build out the running list by retrieving a first new neuron from the running list. In step 525, the method 500 computes one or more activation functions associated with connections between the retrieved neuron and each upstream neuron so that the values can be pulled from the current neuron. Each activation function may include or implement a physics-based transfer function that models how the real sensor value propagates through a physical element represented by the neuron. For example, activation functions may model heat transfer, mass transfer, fluid flow, or other physical phenomena. The activation functions may transform the real sensor value and, in some embodiments, may translate the value from a first value type to a second value type different from the first value type. For example, if the current neuron is neuron 210, the method 500 may compute the activation functions for neurons 215, 221, 231, 241, 261 in this step 525. In an embodiment that uses push propagation, this step 525 may instead calculate only the current neuron's activation function and deliver the resulting value to the downstream neurons. For example, if the current neuron is neuron 210, the method 500 may compute the activation function for neuron 210 and deliver the resulting value to neurons 215, 221, 231, 241, 261 in this step 525.

In step 530, the method 500 resolves one or more transformed values obtained from upstream neurons to determine updated state values for the current neuron. In embodiments where multiple real sensor values have been propagated to the current neuron from different simulated locations, the updated state values may be determined based on a combination of the propagated values. The combination may be performed using physics-based rules, weighted functions, averaging functions, or other resolution rules. In some embodiments, the resolution rule may be tuned over time using machine learning techniques based on observed behavior of the system being modeled. For example, the method may compute the average of all so-pulled values or the average of those values with the previously-stored value at the current neuron. In other embodiments, another rule may be applied to determine how much weight each pulled or previously-stored value should be given in determining what state values will be stored in the current neuron. For example, heat transfer functions may be used along with system properties such as thermal resistances and capacitances to compute the relative contribution of heat from each neighboring neuron. Alternatively, a weighted average function may be employed, and machine learning may be used to turn the weights over time based on observing the real world environment or system being modeled.

In step 535, after the current neuron's state values have been updated, the method 500 identifies additional neurons connected downstream from the current neuron and adds them to the running list for further propagation, if not already processed. As noted above in step 515, the method 500 may take steps to make sure that only unprocessed or unadded neurons are added to the list. In step 540, the method 500 determines whether additional neurons exist in the list for processing. If so, the method 500 loops back to step 520. In this way, the method 500 iterates through the neurons, propagating the measurement from step 510 through multiple activation functions including physics-based transfer functions. After the last neuron is processed, the method 500 proceeds to end in step 545. In some embodiments, the propagated and resolved state values stored at one or more neurons correspond to virtual sensor values for simulated locations that do not have physical sensor devices. These virtual sensor values may be extracted from the digital twin simulation in response to a request from an application, including via an application programming interface, and may be further processed by applying one or more conversion functions prior to output.

In some embodiments, the method 500 may illustrate only a single time-step in a multi-time step simulation. In such embodiments, method 500 may be repeated until the correct number of time steps have been simulated to reach the desired point in the future. In embodiments where the simulation produces a time-value curve, the values may be recorded after each execution of the method 500, such that each series of values is compiled time-step by time-step.

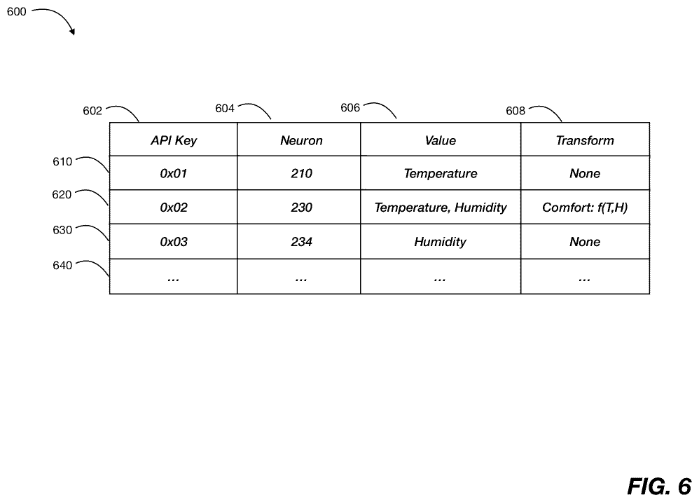

FIG. 6 illustrates an example of a registry 600 for available virtual sensors in a system. The registry 600 may correspond to the virtual device registry 374. As shown, the registry 600 includes fields for an API key 602, neuron 604 value 606, and transform 608. API key field 602 may store a key that is used to authenticate a requesting device as having permission to access a particular sensor, whether virtual or real, or any other available value. Neuron field 604 may store an identification of one or more neurons where sensors are configured that that device is authorized to read. Value field 606 may identify the one or more values that are to be read for the sensor from the identified neuron(s). Transform field 608 may define any transforms that are to be applied upon reading a sensor value.

As an example, device record 610 indicates that requests for API key 0x01 should be served the untransformed temperature value from neuron 210. In this example, the virtual sensor corresponds directly to a stored state value in the digital twin simulation. Device record 620 indicates that API key 0x02 should be served a comfort value by applying a function f(T, H) to the temperature and humidity values read from neuron 230. Finally, device record 630 indicates that API key 0x03 should be served the untransformed humidity value from neuron 234. In this embodiment, the transform field 608 defines a conversion function that combines multiple value types to generate a virtual sensor value distinct from any single stored state value. The registry 600 may include additional record 640, defining other virtual or real sensors available within the system. for example in response to application programming interface requests to create, update, or remove virtual sensors. Such modifications may specify different neurons, different value types, or different transformation functions without requiring changes to the underlying digital twin simulation. In this manner, the registry 600 enables dynamic interpretation of the current state of the digital twin to provide authorized requesting entities with access to real or virtual sensor values in a flexible and extensible manner.

It should be apparent from the foregoing description that various example embodiments of the invention may be implemented in hardware or firmware. Furthermore, various exemplary embodiments may be implemented as instructions stored on a machine-readable storage medium, which may be read and executed by at least one processor to perform the operations described in detail herein. A machine-readable storage medium may include any mechanism for storing information in a form readable by a machine, such as a personal or laptop computer, a mobile device, a tablet, a server, or other computing device. Thus, a machine-readable storage medium may include read-only memory (ROM), random-access memory (RAM), magnetic disk storage media, optical storage media, flash-memory devices, and similar storage media.

It should be appreciated by those skilled in the art that any block diagrams herein represent conceptual views of illustrative circuitry embodying the principles of the invention. Similarly, it will be appreciated that any flow charts, flow diagrams, state transition diagrams, pseudo code, and the like represent various processes which may be substantially represented in machine readable media and so executed by a computer or processor, whether or not such computer or processor is explicitly shown.

Although the various exemplary embodiments have been described in detail with particular reference to certain example aspects thereof, it should be understood that the invention is capable of other embodiments and its details are capable of modifications in various obvious respects. As is readily apparent to those skilled in the art, variations and modifications can be affected while remaining within the spirit and scope of the invention. Accordingly, the foregoing disclosure, description, and figures are for illustrative purposes only and do not in any way limit the scope of the claims.

We claim:

1. A method for simulating a sensor value comprising:
receiving a real sensor value from a sensor device at a first location within a system;
propagating the real sensor value through a digital twin simulation of the system from a first simulated location associated with the first location to a second simulated location associated with a second location within the system, wherein propagating comprises applying at least one physics-based transfer function to the real sensor value;
determining that a virtual sensor value should be generated for the second location within the system; and
extracting the virtual sensor value from the second simulated location of the digital twin simulation.

2. The method of claim 1, wherein:
the real sensor value has a first value type;
the virtual sensor value has a second value type different from the first value type; and
the at least one physics-based transfer function comprises a function that translates from the first value type to the second value type.

3. The method of claim 1, wherein:
the digital twin simulation comprises a neural network,
the first simulated location comprises a first neuron of the neural network,
the second simulated location comprises a second neuron of the neural network, and
the at least one physics-based transfer function is used as at least part of an activation function within the neural network.

4. The method of claim 1, wherein determining that the virtual sensor value should be generated comprises receiving a request from an application for the virtual sensor value via an application programmer interface.

5. The method of claim 1, wherein the system comprises at least one of a building and a system of HVAC equipment.

6. The method of claim 1, wherein extracting the virtual sensor value comprises applying a conversion function to at least one value associated in the digital twin simulation with the second simulated location to produce the virtual sensor value.

7. The method of claim 1, wherein propagating the real sensor value through the digital twin simulation additionally comprises propagating an additional real sensor value received from an additional sensor device from a third simulated location to the second simulated location, whereby the virtual sensor value is based on both the real sensor value and the additional real sensor value.

8. An apparatus for simulating a sensor value comprising:
a memory storing a digital twin simulation of a system; and
a processor configured to:
receive a real sensor value from a sensor device at a first location within the system,
propagate the real sensor value through the digital twin simulation from a first simulated location associated with the first location to a second simulated location associated with a second location within the system, wherein propagating comprises applying at least one physics-based transfer function to the real sensor value,
determine that a virtual sensor value should be generated for the second location within the system, and
extract the virtual sensor value from the second simulated location of the digital twin simulation.

9. The apparatus of claim 8, wherein:
the real sensor value has a first value type;
the virtual sensor value has a second value type different from the first value type; and
the at least one physics-based transfer function comprises a function that translates from the first value type to the second value type.

10. The apparatus of claim 8, wherein:
the digital twin simulation comprises a neural network,
the first simulated location comprises a first neuron of the neural network,
the second simulated location comprises a second neuron of the neural network, and
the at least one physics-based transfer function is used as at least part of an activation function within the neural network.

11. The apparatus of claim 8, wherein, in determining that the virtual sensor value should be generated, the processor is configured to receive a request from an application for the virtual sensor value.

12. The apparatus of claim 8, wherein the system comprises at least one of a building and a system of HVAC equipment.

13. The apparatus of claim 8, wherein, in extracting the virtual sensor value, the processor is configured to apply a conversion function to at least one value associated in the digital twin simulation with the second simulated location to produce the virtual sensor value.

14. The apparatus of claim 8, wherein, in propagating the real sensor value through the digital twin simulation, the processor is additionally configured to propagate an additional real sensor value received from an additional sensor device from a third simulated location to the second simulated location, whereby the virtual sensor value is based on both the real sensor value and the additional real sensor value.

15. A non-transitory machine-readable storage medium encoded with instructions for execution
by a processor for simulating a sensor value, the non-transitory machine-readable storage medium comprising:
instructions for receiving a real sensor value from a sensor device at a first location within a system;
instructions for propagating the real sensor value through a digital twin simulation of the system from a first simulated location associated with the first location to a second simulated location associated with a second location within the system, wherein propagating comprises applying at least one physics-based transfer function to the real sensor value;
instructions for determining that a virtual sensor value should be generated for the second location within the system; and
instructions for extracting the virtual sensor value from the second simulated location of the digital twin simulation.

16. The non-transitory machine-readable storage medium of claim 15, wherein:
the real sensor value has a first value type;
the virtual sensor value has a second value type different from the first value type; and
the at least one physics-based transfer function comprises a function that translates from the first value type to the second value type.

17. The non-transitory machine-readable storage medium of claim 15, wherein:
the digital twin simulation comprises a neural network, the first simulated location comprises a first neuron of the neural network, the second simulated location comprises a second neuron of the neural network, and the at least one physics-based transfer function is used as at least part of an activation function within the neural network.

18. The non-transitory machine-readable storage medium of claim 15, wherein the instructions for determining that the virtual sensor value should be generated comprise instructions for receiving a request from an application for the virtual sensor value via an application programmer interface.

19. The non-transitory machine-readable storage medium of claim 15, wherein the instructions for extracting the virtual sensor value comprise instructions for applying a conversion function to at least one value associated in the digital twin simulation with the second simulated location to produce the virtual sensor value.

20. The non-transitory machine-readable storage medium of claim 15, wherein the instructions for propagating the real sensor value through the digital twin simulation additionally comprise instructions for propagating an additional real sensor value received from an additional sensor device from a third simulated location to the second simulated location, whereby the virtual sensor value is based on both the real sensor value and the additional real sensor value.
